(19) United States
(12) Patent Application Publication
(10) Pub. No.: US 2025/0059100 A1
(43) Pub. Date: Feb. 20, 2025

(54) MULTIPLE SHAPER FOR GAS PHASE INFILTRATION

(71) Applicant: SAFRAN CERAMICS, LE HAILLAN (FR)

(72) Inventors: Franck LAMOUROUX, MOISSY-CRAMAYEL (FR); Simon Lucien René THIBAUD, MOISSY-CRAMAYEL (FR)

(21) Appl. No.: 18/721,428

(22) PCT Filed: Dec. 14, 2022
(86) PCT No.: PCT/FR2022/052353

§ 371 Date: Jun. 18, 2024

(30) Foreign Application Priority Data
Dec. 20, 2021 (FR) FR2113971

(51) Int. Cl. C04B 35/628; C04B 35/80

(52) U.S. Cl. CPC C04B 35/62884; C04B 35/80; C04B 2235/5252; C04B 2235/614

(57) ABSTRACT

A load for placement in a chemical vapor infiltration consolidation or densification installation, the load including fibrous preforms disposed in a shaper for consolidating or densifying fibrous preforms in the gas phase, the shaper including a plurality of shaping housings, each shaping housing being formed by a first surface and a second surface facing each other and being intended to receive a fibrous preform, each first or second surface including retaining elements projecting from the surface and extending to an end face intended to be in contact with the fibrous preform, each shaping housing extending between at least one gas inlet and at least one gas outlet positioned between the first surface and the second surface of the housing, the shaper including a start plate, an end plate and one or more intermediate plates positioned between the start plate and the end plate.

### TECHNICAL FIELD

The present invention concerns the manufacture of composite material parts and, more particularly, shaping tools used during the consolidation or densification by chemical vapor infiltration of a fibrous preform intended to form at least the reinforcement of the composite material part.

### PRIOR ART

Consolidation or densification by chemical vapor infiltration (CVI) is conventionally carried out by placing the fibrous preform to be consolidated or densified in a multiperforated graphite shaper, itself placed in a furnace or reactor where it is heated. Such a multiperforated shaper is described, for example, in document FR 3,021,671 or in document FR 3,059,679.

A reactive gas containing one or more gaseous precursors of the matrix material is introduced into the reactor. The temperature and the pressure in the reactor are adjusted to allow the reactive gas to diffuse into the pores of the fibrous preform via the perforations of the shaper. The reactive gas can thus form a deposit of the constituent material of the matrix by decomposition of one or more constituents of the reactive gas or reaction between several constituents, these constituents forming the matrix precursor. In addition, by this process, an interphase material can be deposited with the matrix.

However, this consolidation or densification technique conventionally requires a very cumbersome graphite tool comprising large multiperforated walls. On the one hand, since perforated graphite is fragile, the shaping tool must have thick walls. On the other hand, large, bolted joints are required to close and hold the shaping tool supports. Thus, it is not possible to place a large number of shapers at the same time in the space available in the furnace or reactor, especially since all the perforated surfaces must be easily accessible to the gas circulating in the reactor to guarantee satisfactory consolidation or densification. The number of fibrous preforms that can be densified or consolidated simultaneously in the reactor is therefore very small and does not allow high-speed production.

There are also shaping tools in which the fibrous preform is pressed against surfaces without perforations. Such a configuration is described, for example, in document FR 3,107,283, in which the gas inlet is placed at one end of the preform and the gas outlet is placed at the other end of the preform. Such shaping tools are used in a small, insulated installation, comprising a heating system. This configuration is therefore not suitable for mass production.

### DISCLOSURE OF THE INVENTION

The object of the present invention is to remedy the disadvantages described above, by proposing a shaper suited to high-speed production.

To this end, the invention proposes a shaper for the consolidation or densification in the gas phase of fibrous preforms, characterized in that it comprises a plurality of shaping housings, each shaping housing being formed by a first surface and a second surface facing each other and being intended to receive a fibrous preform, each first or second surface comprising retaining elements projecting from said surface and extending to an end face intended to contact the fibrous preform, each shaping housing extending between at least one gas inlet and at least one gas outlet positioned between the first surface and the second surface of said housing.

Thus, the shaper according to the invention makes it possible to simultaneously consolidate or densify a large number of fibrous preforms with a small footprint. By placing the gas inlet(s) at one end of each shaping housing and the gas outlet(s) at the other end of each shaping housing, satisfactory consolidation or densification of each fibrous preform is ensured. In fact, the shaper has at least one gas inlet and at least one gas outlet specific to each shaping housing. Thus, the gas that enters a shaping housing has not previously circulated into another shaping housing of the shaper, which improves the quality of consolidation or densification of the fibrous preforms. In addition, the face(s) of the shaper comprising the gas inlets are easily accessible for the reactive gas, since access is not impeded by an adjacent shaper.

According to a particular characteristic of the invention, the shaper comprises a start plate, an end plate and one or more intermediate plates positioned between the start plate and the end plate, each intermediate plate comprising the first surface of a shaping housing and the second surface of an adjacent shaping housing.

Thus, the shaper has a very compact configuration, each intermediate plate being used simultaneously for two adjacent shaping housings.

The term “end face” denotes the surface of the retaining element that will actually be in contact with the fibrous preform disposed in the shaper. Thus, the entire end face of a retaining element must be in contact with the fibrous preform when the preform is placed in the shaper.

According to a particular characteristic of the invention, each shaping housing is intended to receive a fibrous preform, said fibrous preform being intended to form the fibrous reinforcement of an aircraft engine part.

According to a particular characteristic of the invention, the sum of the areas of the end faces of the retaining elements of each first or second surface is less than or equal to 50% of the total area of said surface.

Preferably, the sum of the areas of the end faces of the retaining elements of each first or second surface is less than or equal to 40% of the total area of said surface, and preferably greater than or equal to 5% of the total area of said surface.

Thus, when the fibrous preforms are placed in the shaping housings, the surface area of the fibrous preform in contact with the reactive gas is very high, which improves the kinetics of the consolidation or densification operation. In addition, the appearance of unwanted local excess thicknesses in the fibrous preform is further limited while simplifying maintenance of the shaper.

According to another particular characteristic of the invention, the area of the end face of at least one retaining element is comprised between 1 mm² and 50 mm². Preferably, the area of the end face of at least one retaining element is comprised between 2.5 mm² and 15 mm².

According to another particular characteristic of the invention, the area of the end face of at least one retaining element is less than 1 mm².

In this embodiment, the contact between the retaining element and the fibrous preform is called a point contact. At least a portion of the retaining elements can thus have, for example, the overall shape of a needle, a straight rod or a rod curved into an arc or “C” shape.

This guarantees better circulation of the gas flows in the vicinity of the fibrous preforms disposed in the shaper, by further reducing the contact area between the fibrous preforms and the shaper.

According to a particular characteristic of the invention, at least a portion of the retaining elements have a frustoconical or cylindrical shape.

A “frustoconical” retaining element should be understood as a retaining element having a frustoconical geometry. The term “cone” refers to a solid or hollow volume whose surface is defined by a line passing through a fixed point and a variable point describing a closed curve. The term “cone” can therefore designate any cone and does not necessarily designate a cone of revolution.

A “cylindrical” retaining element should be understood as a retaining element having a cylindrical geometry. The term “cylinder” designates a solid or hollow volume defined by a ruled surface whose generating lines are parallel. The term “cylinder” can therefore designate any cylinder and does not necessarily designate a straight cylinder or cylinder of revolution.

However, preferably, at least a portion of the retaining elements have a frustoconical shape of revolution, and/or at least a portion of the retaining elements have a cylindrical shape of revolution.

According to a particular characteristic of the invention, at least a portion of the retaining elements have the shape of a polyhedron having at least two faces in the form of a trapezium.

According to a particular characteristic of the invention, at least a portion of the retaining elements of each first or second surface has a section that decreases progressively from their junction with said surface to their end face intended to come into contact with the fibrous preform.

Such a progressive reduction in the section of the retaining elements gives them a certain robustness, while obtaining an end face that is as small as possible. Thus, it is possible to increase the surface area of the preform in contact with the reactive gas during the consolidation or densification operation without weakening the shaper.

In order to simplify the manufacture of the shaper, all the retaining elements of the same surface can have the same geometrical shape and/or the same dimensions. In order to simplify the manufacture of the shaper, all the first surfaces can have an identical geometry and all the second surfaces can have an identical geometry. Thus, the intermediate plates of the shaper can have an identical geometry.

The invention also proposes a load intended to be placed in an installation for consolidation or densification by chemical vapor infiltration, said load comprising a plurality of fibrous preforms disposed in a shaper according to the invention, in such a way that each fibrous preform disposed in a shaping housing is held by the end faces of the retaining elements of said housing.

According to a particular characteristic of the invention, the fibrous preforms are preforms of aircraft engine parts.

According to a particular characteristic of the invention, the gas inlet of each shaping housing is located between the first surface of said housing and the fibrous preform present in said housing, and the gas outlet of the housing is located between the second surface of said housing and the fibrous preform in said housing.

This configuration allows improving the consolidation or densification of the fibrous preform, because the gas must pass through the fibrous preform to be able to exit.

The invention also concerns a method for manufacturing several composite material parts comprising:
the placement of several fibrous preforms, possibly pre-consolidated or consolidated, in a shaper according to the invention, so that each fibrous preform disposed in a shaping housing is held by the end faces of the retaining elements of said housing, and
the densification of the fibrous preforms by chemical vapor infiltration.

In one embodiment, the invention provides a method for manufacturing multiple composite material parts comprising:
the placement of several porous fibrous preforms in a shaper according to the invention, so that each fibrous preform arranged in a shaping housing is held by the end faces of the retaining elements of said housing, and
the consolidation of porous fibrous preforms by chemical vapor infiltration of a matrix, and
the densification of the consolidated preforms.

### BRIEF DESCRIPTION OF THE DRAWINGS

FIG. 1 is a schematic view illustrating a load comprising a shaper in accordance with one embodiment of the invention.

FIG. 2 is a schematic cross-sectional view of the load of FIG. 1.

FIG. 3 is a schematic view of the first surface of an intermediate plate of the shaper of FIGS. 1 and 2.

FIG. 4 is a schematic view of the second surface of the intermediate plate of FIG. 3.

FIG. 5 is a schematic cross-sectional view illustrating a load comprising a shaper in accordance with another embodiment of the invention.

FIG. 6 is a schematic cross-sectional view of a chemical vapor infiltration densification installation according to a first embodiment of the invention comprising the load of FIG. 5.

FIG. 7 is a schematic view of an installation for densification by vapor infiltration according to a second embodiment of the invention comprising the load of FIGS. 1 and 2.

### DESCRIPTION OF THE EMBODIMENTS

The present invention applies to the manufacture of parts made of composite material and, in particular, of the SiC/SiC type. More particularly, the invention finds an advantageous application during the steps of consolidation or densification of fibrous preforms by chemical vapor infiltration.

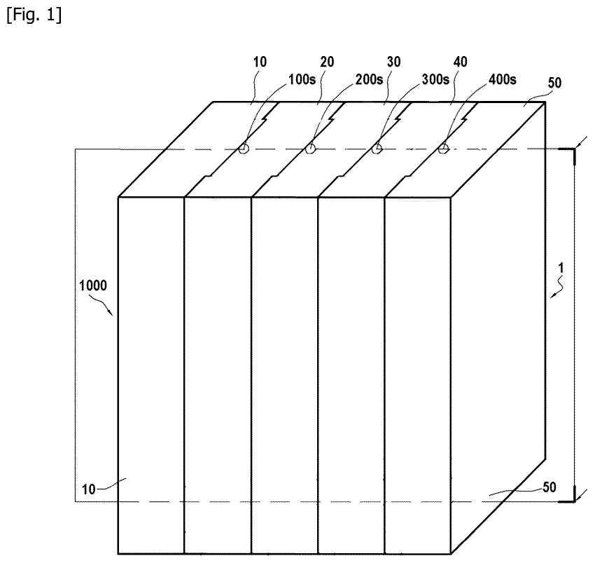

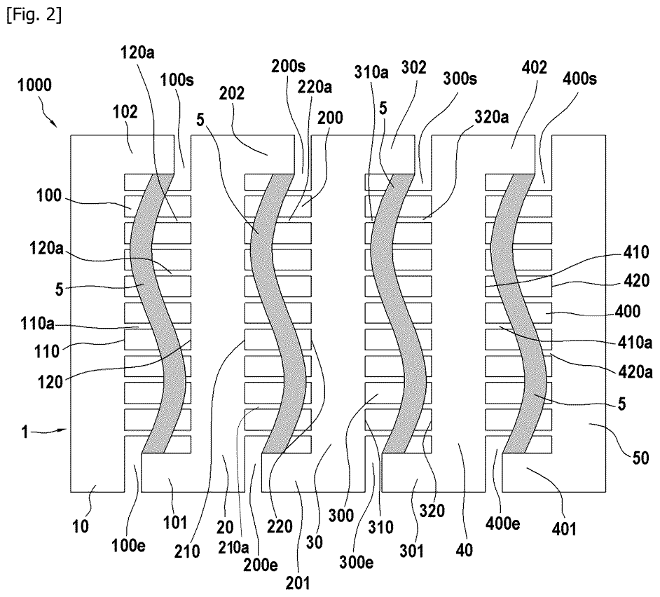

FIGS. 1 and 2 illustrate the production of a load 1000 comprising the fibrous preforms 5 disposed in a shaper 1 in accordance with one embodiment of the invention. Once completed, the load 1000 is intended to be introduced into a reaction chamber of a chemical vapor infiltration installation.

Each fibrous preform 5 corresponds to a “dry” fibrous texture, i.e., not impregnated with a resin or the like. The fibrous preforms 5 can comprise a plurality of yarns of various types, in particular ceramic or carbon yarns or a mixture of such yarns. Preferably, the preforms 5 can be made from silicon carbide fibers. In general, preforms 5 can also be made from fibers made of the following materials: alumina, mullite, silica, aluminosilicate, borosilicate, carbon, or a mixture of these materials.

Each fibrous preform 5 can be obtained from at least one textile operation using ceramic and/or carbon yarns. The preforms 5 can be made by stacking strata or plies obtained by two-dimensional weaving (2D). Here, “two-dimensional weaving” means a conventional weaving method in which each weft yarn passes from one side to the other of yarns of a single warp layer or vice versa.

The fibrous preforms 5 can, in particular, be obtained by multi-layer or three-dimensional weaving of the yarns. The term “three-dimensional weaving” or “3D weaving” should be understood to mean a weaving method by which at least some of the warp yarns bind weft yarns on several weft layers. The roles of the warp and weft can be reversed.

The fibrous preforms 5 can, for example have a multi-satin pattern, i.e. a weave obtained by three-dimensional weaving with several layers of weft yarns whose base pattern of each layer is equivalent to a conventional satin pattern but with certain points of the pattern that bind the layers of weft yarns together. As a variant, the fibrous preforms 5 can have a 3D weaving pattern for which each layer of warp yarns binds several layers of weft yarns with all the yarns of the same warp column having the same movement in the plane of the pattern. Various multilayer weaving methods that can be used to form the fibrous preforms are described in document WO 2006/136755.

The fibrous preforms 5 can also be made of sheets of unidirectional fibers (UD) which can be obtained by automated fiber placement (AFP) or by linear winding.

It is also possible to start from fibrous textures such as two-dimensional fabrics or unidirectional (UD) sheets, and to obtain each fibrous preform 5 by draping such fibrous textures on a form. These textures can optionally be bound together, for example by stitching, by implanting yarns or rigid elements, or by needle punching to form the fibrous preform.

The shaper according to the invention comprises at least two shaping housings, each shaping housing being intended to receive a fibrous preform.

The shaper 1 illustrated in FIGS. 1 and 2 comprises, by way of example, four shaping housings 100, 200, 300 and 400, each shaping housing 100, 200, 300, 400 receiving a fibrous preform 5. Of course, it does not exceed the scope of the invention if the shaper comprises two, three or more shaping housings.

In the configuration shown in FIGS. 1 and 2, this corresponds to a structural enclosure comprising a start plate 10, three intermediate plates 20, 30 and 40 and an end plate 50. The intermediate plates 20, 30 and 40 separate and delimit the shaping housings 100, 200, 300, 400 from one another. The start plate 10 and end plate 50 make it possible to close the shaping housings 100 and 400 situated at the ends of the shaper 1. The fibrous preforms 5 are interposed in the shaping housings 100, 200, 300, 400 between the start plate 10, the intermediate plates 20, 30, and 40 and the end plate 50.

Each shaping housing 100, 200, 300, 400 is formed by a first surface 110, 210, 310, 410 and a second surface 120, 220, 320, 420 facing the first surface 110, 210, 310, 410. The first surface 110, 210, 310, 410 belongs to the start plate 10 or to an intermediate plate 20, 30, 40. The second surface 120, 220, 320, 420 belongs to an intermediate plate 20, 30, 40 or to the end plate 50.

Thus, the start plate 10 comprises the first surface 110 of a first shaping housing 100. The first intermediate plate 20, i.e., the intermediate plate closest to the start plate 10, comprises the second surface 120 of the first shaping housing 100. Thus, the first shaping housing 100 is defined by the first surface 110 belonging to the start plate 10 and by the second surface 120 belonging to the first intermediate plate 20.

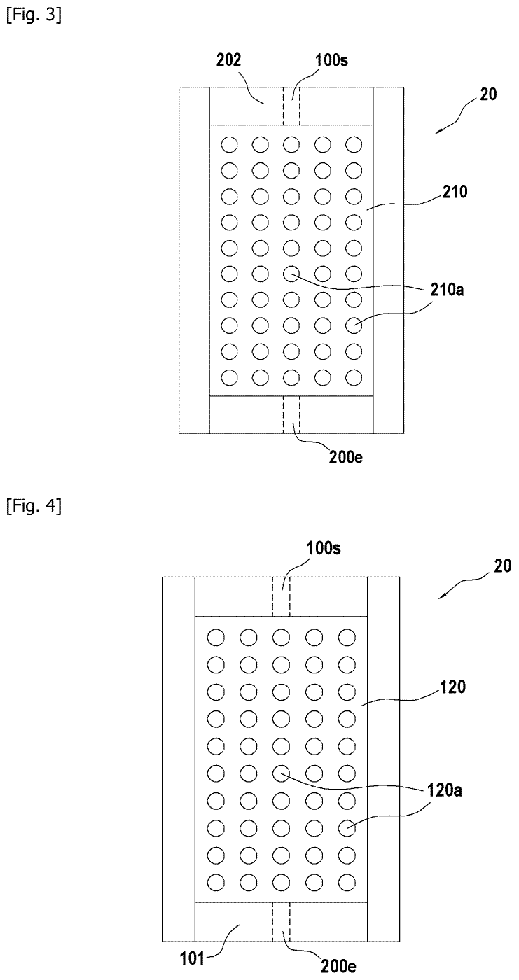

The first intermediate plate 20 further comprises the first surface 210 of a second shaping housing 200. The first intermediate plate 20 thus comprises at least two opposite faces, one corresponding to the second surface 120 of the first shaping housing 100, the other corresponding to the first surface 210 of the second shaping housing 200, as illustrated schematically in FIGS. 3 and 4.

The second intermediate plate 30, i.e., the intermediate plate closest to the first intermediate plate 20, comprises the second surface 220 of the second shaping housing 200. Thus, the second shaping housing 200 is defined by the first surface 210 belonging to the first intermediate plate 20 and by the second surface 220 belonging to the second intermediate plate 30.

The second intermediate plate 30 further comprises the first surface 310 of a third shaping housing 300. The second intermediate plate 30 thus comprises at least two opposite faces, one corresponding to the second surface 220 of the second shaping housing 200, the other corresponding to the first surface 310 of the third shaping housing 300.

The third intermediate plate 40, i.e., the intermediate plate closest to the end plate 50, comprises the second surface 320 of the third shaping housing 300. Thus, the third shaping housing 300 is defined by the first surface 310 belonging to the second intermediate plate 30 and by the second surface 320 belonging to the third intermediate plate 40.

The third intermediate plate 40 further comprises the first surface 410 of a fourth shaping housing 400. The third intermediate plate 40 thus comprises at least two opposite faces, one corresponding to the second surface 320 of the third shaping housing 300, the other corresponding to the first surface 410 of the fourth shaping housing 400.

The end plate 50 comprises the second surface 420 of the fourth shaping housing 400. Thus, the fourth shaping housing 400 is defined by the first surface 410 belonging to the third intermediate plate 40 and by the second surface 420 belonging to the end plate 50.

Each shaping housing 100, 200, 300, 400 extends along its first surface 110, 210, 310, 410 and its second surface 120, 220, 320, 420 between a first end 101, 201, 301, 401 and a second end 102, 202, 302, 402. Each shaping housing 100, 200, 300, 400 comprises at least one gas inlet 100e, 200e, 300e, 400e positioned at the first end 101, 201, 301, 401 of said shaping housing 100, 200, 300, 400, and opening into the shaping housing 100, 200, 300, 400 between the first surface 110, 210, 310, 410 and the second surface 120, 220, 320, 420 of said housing 100, 200, 300, 400. Each shaping housing 100, 200, 300, 400 further comprises at least one gas outlet 100s, 200s, 300s, 400s positioned at the second end 102, 202, 302, 402 of said shaping housing 100, 200, 300, 400, and opening into the shaping housing 100, 200, 300, 400 between the first surface 110, 210, 310, 410 and the second surface 120, 220, 320, 420 of said housing 100, 200, 300, 400.

Preferably, the first ends 101, 201, 301, 401 of all the shaping housings 100, 200, 300, 400 are located on one side of the shaper 1 and the second ends 102, 202, 302, 402 of all the shaping housings 100, 200, 300, 400 are located on another side of said shaper 1. Thus, preferably, the gas inlets 100e, 200e, 300e, 400e of the shaper 1 are all located on the same side, and the gas outlets 100s, 200s, 300s, 400s of the shaper 1 are all located on the same side, opposite that of the gas inlets 100e, 200e, 300e, 400e. This facilitates the arrangement of the shaper 1 in the chemical vapor infiltration installation, and the possible connections of the gas inlets and outlets.

According to a particular embodiment of the invention illustrated in FIG. 2, when a fibrous preform 5 is disposed in a shaping housing 100, 200, 300, 400 of the shaper 1, the gas inlet(s) 100e, 200e, 300e, 400e of the housing 100, 200, 300, 400 are situated solely between the first surface 110, 210, 310, 410 of said housing and the preform 5, at the first end 101, 201, 301, 401 of the shaping housing 100, 200, 300, 400. In addition, the gas outlet(s) 100s, 200s, 300s, 400s of the housing 100, 200, 300, 400 are located solely between the second surface 120, 220, 320, 420 of said housing and the preform 5, at the second end of the housing 102, 202, 302, 402. It is of course possible to reverse the role of the first surface of the housing and of the second surface of the housing without departing from this embodiment.

According to another particular embodiment of the invention, when a fibrous preform is disposed in a shaping housing of the shaper, the gas inlet(s) of the shaping housing can be located both between the first surface of the housing and the preform, and between the second surface of the housing and the preform, at the first end of the shaping housing. In addition, the gas outlet(s) of the shaping housing can be located both between the first surface of the housing and the preform, and between the second surface of the housing and the preform, at the second end of the shaping housing.

Each first or second surface 110, 210, 310, 410, 120, 220, 320, 420 of each shaping housing 100, 200, 300, 400 has retaining elements 110a, 210a, 310a, 410a, 120a, 220a, 320a, 420a projecting from said surface 110, 210, 310, 410, 120, 220, 320, 420. These retaining elements can take the form of protrusions or reliefs extending from the first or second surface to the opposite surface. These retaining elements thus extend as far as an end face intended to be in contact with the fibrous preform disposed in the shaping housing.

When a fibrous preform 5 is placed in a shaping housing 100, 200, 300, 400 of a shaper 1 according to the invention, the retaining elements 110a, 210a, 310a, 410a, 120a, 220a, 320a, 420a of the shaping housing 100, 200, 300, 400 extend between the fibrous preform 5 and the first or second surface 110, 210, 310, 410, 120, 220, 320, 420. Gas can thus circulate between the fibrous preform 5 and the first or second surface 110, 210, 310, 410, 120, 220, 320, 420 of the shaping housing 100, 200, 300, 400 during the consolidation or densification step.

At least a portion of the retaining elements of a surface can have a frustoconical shape, and preferably a frustoconical shape of revolution. At least a portion of the retaining elements of a surface can have a cylindrical shape, and preferably a cylindrical shape of revolution, as is the case in the examples illustrated in the figures. At least a portion of the retaining elements of a surface can have the shape of a polyhedron, preferably having two trapezoidal faces, or even four trapezoidal faces distinct from the end face. The retaining elements can take the form of grooves defining channels for the flow of the reactive gas.

Preferably, at least a portion of the retaining elements has a section that decreases progressively from their junction with the first or second surface to their end face. Such a progressive reduction in the section of the retaining elements in their direction of extension makes it possible to give them better strength, while obtaining an end face of the smallest possible area for contact with the fibrous preform.

Preferably, the sum of the areas of the end faces of the retaining elements 110a, 210a, 310a, 410a, 120a, 220a, 320a, 420a of the first or second surface 110, 210, 310, 410, 120, 220, 320, 420 is less than or equal to 50% of the total area of said surface, in order to expose the largest possible surface of the fibrous preform 5 to the reactive gas. Preferably, the sum of the areas of the end faces of the retaining elements 110a, 210a, 310a, 410a, 120a, 220a, 320a, 420a of the first or second surface 110, 210, 310, 410, 120, 220, 320, 420 is less than or equal to 40% of the total area of said surface, and preferably greater than or equal to 5% of the total area of said surface.

Preferably, the area of the end face of at least a portion of the retaining elements 110a, 210a, 310a, 410a, 120a, 220a, 320a, 420a is between 1 mm² and 50 mm². Preferably, the area of the end face of at least a portion of the retaining elements 110a, 210a, 310a, 410a, 120a, 220a, 320a, 420a is between 2.5 mm² and 15 mm².

According to another embodiment of the invention, the contact between at least a portion of the retaining elements and the fibrous preforms is called a point contact, i.e., the end face area of at least a portion of the retaining elements is less than 1 mm². At least a portion of the retaining elements can have, for example, the overall shape of a needle, a straight rod or a rod curved into an arc or “C” shape.

Of course, it does not exceed the scope of the invention if the retaining elements have another shape or geometry, other dimensions, or a distribution different from those described in the present application. In particular, the retaining elements can form various groupings between two surfaces, or even within the same surface.

In the example illustrated in FIGS. 1 and 2, the first surface 110, 210, 310, 410 and the second surface 120, 220, 320, 420 of each housing 100, 200, 300, 400 are flat. Of course, it does not exceed the scope of the invention if the first surface and the second surface of the shaping housing have curvatures, especially to adapt to any curvatures of the preform to be disposed in said shaping housing. When the first surface and the second surface of each housing do not have the same shape or geometry as the faces of the fibrous preform disposed in said housing, as is the case in the example illustrated in FIGS. 1 and 2, the retaining elements present on the first surface and the second surface can have varying lengths in the direction extending between the first or second surface and the fibrous preform. Thus, preferably, the end faces of the retaining elements intended to be in contact with the fibrous preform define a geometry identical to that of the fibrous preform.

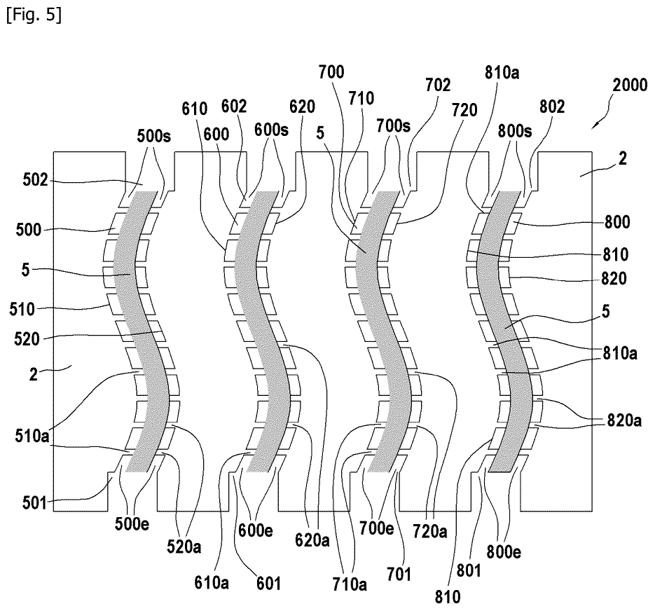

In the embodiment illustrated in FIG. 5, the shaper 2, intended to receive fibrous preforms 5 identical to those of the embodiment described above in order to form a load 2000, comprises four shaping housings 500, 600, 700 and 800. As previously, the four shaping housings 500, 600, 700 and 800 are respectively defined by a first surface 510, 610, 710, 810 and by a second surface 520, 620, 720, 820. Each first or second surface 510, 610, 710, 810, 520, 620, 720, 820 of each shaping housing 500, 600, 700, 800 has retaining elements 510a, 610a, 710a, 810a, 520a, 620a, 720a, 820a projecting from said surface 510, 610, 710, 810, 520, 620, 720, 820. These retaining elements can have the same characteristics as in the embodiment described above.

In this embodiment, the first surface 510, 610, 710, 810 and the second surface 520, 620, 720, 820 of each shaping housing 500, 600, 700 and 800 have a geometry identical to the surfaces of the preform 5. Thus, the retaining elements 510a, 610a, 710a, 810a, 520a, 620a, 720a, 820a present on the first surface 510, 610, 710, 810 and the second surface 520, 620, 720, 820 preferably have identical lengths in the direction extending between said first or second surface and the fibrous preform 5.

In this embodiment, the gas inlet(s) of each shaping housing can be located solely between the first surface of the housing and the preform, and the gas outlet(s) of each shaping housing can be located solely between the second surface of the housing and the preform, or vice versa, as described above.

As in the example illustrated in FIG. 5, the gas inlet(s) 500e, 600e, 700e, 800e of each shaping housing 500, 600, 700, 800 can also be located both between the first surface 510, 610, 710, 810 of said housing and the preform 5, and between the second surface 520, 620, 720, 820 of the housing and the preform 5, at the first end 501, 601, 701, 801 of the shaping housing 500, 600, 700, 800. In addition, the gas outlet(s) 500s, 600s, 700s, 800s of each shaping housing 500, 600, 700, 800 can be located both between the first surface 510, 610, 710, 810 of said housing and the preform 5, and between the second surface 520, 620, 720, 820 of the housing and the preform 5 at the second end 502, 602, 702, 802 of the shaping housing 500, 600, 700, 800.

The fibrous preforms 5 are placed in the appropriate shaper 1 or 2 for the purpose of consolidating or densifying them by chemical vapor infiltration. In the case of consolidation by chemical infiltration, the fibrous preforms may have been pre-consolidated before being placed in the shaper. This pre-consolidation step makes it possible to confer sufficient stiffness to the fibrous preforms, so that they can be easily supported and positioned by the retaining elements. For example, the fibrous preforms can undergo a pre-shaping step using resin or any other fugitive material. This pre-consolidation can also improve the reproducibility of positioning of the fibrous preforms in the shaper.

The shaper 1 or 2 is closed by clamping members consisting here of screws and nuts; spacers can be used to adjust the fit between the start plate, the intermediate plates and the end plate. The fibrous preforms 5 and the shaper 1 or 2 constitute a load 1000 or 2000 which is placed in a chemical vapor infiltration installation or furnace.

The shaper according to the invention is compatible with various installations for chemical vapor infiltration, including installations conventionally intended for multiperforated shapers, described, for example, in documents FR 3,021,671 or FR 3,059,679.

In the case of an installation with a conventional reactor, it is necessary to guide the gases to the inlet of the shaper. Preferably, the installation comprises one or more guiding means used to introduce the reactive gas(s) into one or more gas inlets of the shaper.

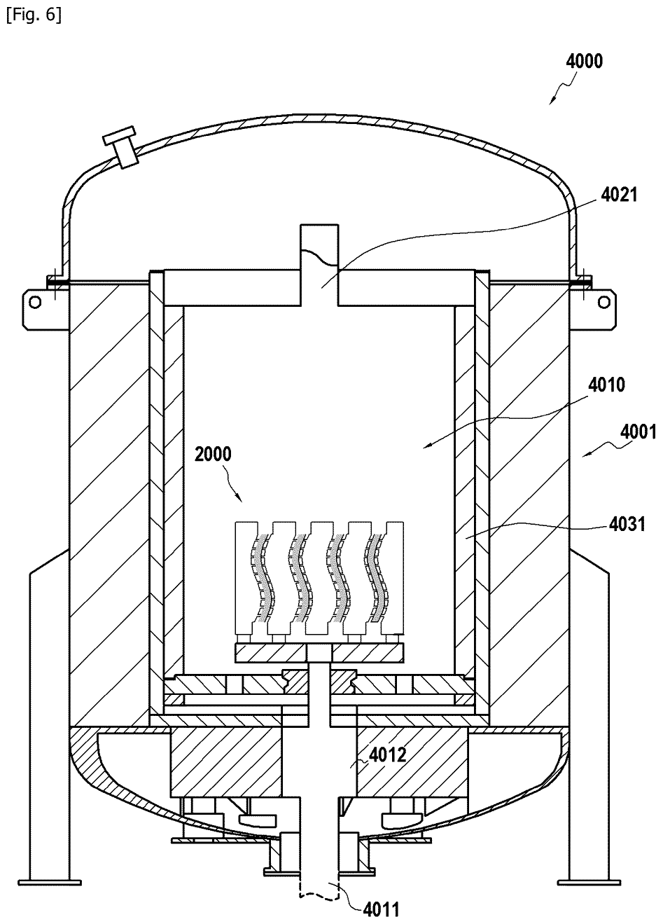

According to a first example illustrated schematically in FIG. 6, the gas phase chemical infiltration installation 4000 comprises an enclosure 4001, for example cylindrical, delimiting a reaction chamber 4010 equipped with a gas inlet conduit 4011 which can open into a homogenization zone 4012 allowing the gas or gases to be homogenized before diffusion into the reaction chamber 4010. The reaction chamber 4010 comprises a support onto which the load 2000, comprising the shaper 2 and the fibrous preforms 5, is intended to be deposited. The residual gases are extracted at the top of the installation by a discharge conduit 4021 which is connected to suction means (not shown). The heating is produced, for example, by a susceptor 4031.

The preforms 5 are consolidated or densified by chemical vapor infiltration. In order to consolidate or densify the preforms 5, a reactive gas containing at least one or more precursors of the matrix material to be deposited is introduced into the reaction chamber. In the case of a ceramic material, such as silicon carbide (SIC) here, methyltrichlorosilane (MTS) can be used as the SiC precursor, in a manner well known in itself. In the case of carbon, for example, gaseous hydrocarbon compounds are used, typically propane, methane or a mixture of the two.

The porous preforms 5 are consolidated or densified in a manner well known in itself, by depositing therein the matrix material produced by decomposition of the precursor or precursors contained in the reactive gas diffusing inside the accessible internal porosity of each preform. The gas penetrates into each shaping housing 500, 600, 700, 800 of the shaper 2 via the gas inlet(s) 500e, 600e, 700e, 800e positioned at the first end 501, 601, 701, 801 of said housing. The gas then circulates between the surface or surfaces defining the shaping housing 500, 600, 700, 800 and the fibrous preform 5 disposed inside said shaping housing, while diffusing inside the preform 5. The gas then leaves each shaping housing 500, 600, 700, 800 via the gas outlet(s) 500s, 600s, 700s, 800s positioned at the second end of said housing.

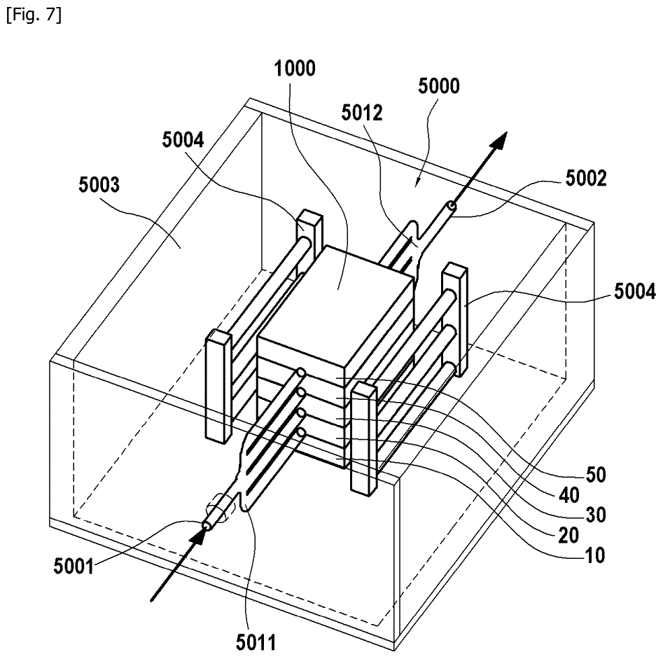

According to a second example illustrated in FIG. 7, the chemical vapor infiltration installation 5000 comprises an enclosure 5003 heated by heating means. For example, heating can be provided by radiation and convection via graphite bars 5004 disposed close to the shaper 1000. The chemical vapor infiltration installation 5000 according to this example further comprises a gas phase source (not shown) which penetrates through the gas inlet 5001 and a multiple conduit 5011 for conveying the reactive gas receiving said gas from the gas phase source. The multiple conveying conduit 5011 makes it possible to introduce the reactive gas into several shaping housings 100, 200, 300, 400 at the same time, through the gas inlet(s) 100e, 200e, 300e, 400e present at the first end 101, 201, 301, 401 of each housing. Preferably, the multiple conveying conduit 5011 makes it possible to supply all of the shaping housings 100, 200, 300, 400 of the shaper 1 loaded into the installation 5000.

It is possible to have several separate gas phase sources, allowing the user to choose which of the sources they wish to connect to the multiple conveying conduit 5011. Such an embodiment especially makes it possible to carry out two successive treatments of the same plurality of fibrous preforms simply by connecting the multiple conveying conduit 5011 to another gas source. This embodiment is particularly advantageous when it is desired to deposit an interphase on the fibrous preforms before they are densified.

The outlet of the gas from each shaping housing 100, 200, 300, 400 takes place via the gas outlet(s) 100s, 200s, 300s, 400s present at the second end 102, 202, 302, 402 of the housing, preferably by means of a multiple gas discharge conduit 5012. The gas is then discharged via a gas outlet 5002.

A tool according to this second example advantageously makes it possible to use a minimum quantity of reactive gas, almost all of which is introduced into the shaping housings of the shaper, unlike the tool according to the first example.

In all the configurations, densification or consolidation can be carried out with so- called directed flow. In this configuration, the gas enters each shaping housing on either side of the preform, that is, the reactive gas enters simultaneously between the first surface of the shaping housing and the fibrous preform and between the second surface of the shaping housing and the fibrous preform at the first end of the shaping housing. In addition, the outlet of the gas from each shaping housing also occurs on either side of the preform, that is, the reactive gas exits simultaneously between the first surface of the shaping housing and the fibrous preform and between the second surface of the shaping housing and the fibrous preform at the second end of the shaping housing.

Densification or consolidation can also be carried out with so-called semi-forced flow. In this configuration, the entry of gas into each shaping housing is only on one side of the preform, and the exit of gas from each shaping housing is only on one side of the preform, different from the side used for the entry. The gas is thus forced to pass through the fibrous preform disposed in the shaping housing. For example, the reactive gas can enter only between the first surface of the shaping housing and the fibrous preform at the first end of said shaping housing and exit only between the second surface of the shaping housing and the fibrous preform, at the second end of said housing.

The pressure and temperature conditions necessary to obtain deposits of various matrices by chemical vapor infiltration are well known in themselves. A pressure gradient can be established between the reactive gas supply point(s) and the reactive gas discharge point(s) to facilitate the passage of reactive gas flows through the preform.

The installations described above thus especially make it possible to consolidate fibrous preforms by vapor infiltration. The consolidated fibrous preforms can then be densified, by a gaseous, liquid or solid route, in a well-known manner. The installations described above also make it possible to densify fibrous preforms by gas. Thus, densification of the preforms makes it possible to form composite material parts, in particular ceramic matrix composites (CMC) such as SiC/SiC composites. The shaper according to the invention thus makes it possible in particular, but not exclusively, to produce parts made of composite material having excellent mechanical properties at high temperature and in an oxidizing environment, such as, for example, parts of aeronautical engines.

The expression “comprised between . . . and . . . ” should be understood to include the bounds.

1. A load for placement in a chemical vapor infiltration consolidation or densification installation, said load comprising a plurality of fibrous preforms disposed in a shaper for consolidating or densifying fibrous preforms in the gas phase, the shaper comprising a plurality of shaping housings, each shaping housing being formed by a first surface and a second surface facing each other and being intended to receive a fibrous preform, each first or second surface comprising retaining elements projecting from said surface and extending to an end face intended to be in contact with the fibrous preform, each shaping housing extending between at least one gas inlet and at least one gas outlet positioned between the first surface and the second surface of said housing,
the shaper comprising a start plate, an end plate and one or more intermediate plates positioned between the start plate and the end plate, each intermediate plate comprising the first surface of a shaping housing and the second surface of an adjacent shaping housing, each fibrous preform disposed in a shaping housing being held by the end faces of the retaining elements of said housing.

2. (canceled)

3. The load according to claim 1, wherein a sum of areas of the end face of the retaining elements of each first or second surface is less than or equal to 50% of the total area of said surface.

4. The load according to claim 1, wherein the end face area of at least one retaining element is comprised between 1 mm² and 50 mm².

5. The load according to claim 1, wherein the area of the end face of at least one retaining element is less than 1 mm².

6. The load according to claim 1, wherein at least a portion of the retaining elements has a frustoconical or cylindrical shape.

7. The load according to claim 1, wherein at least a portion of the retaining elements have the shape of a polyhedron having at least two faces in the form of a trapezium.

8. The load according to claim 1, wherein at least a portion of the retaining elements of each first or second surface has a section which gradually decreases from their junction with said surface to their end face intended to come into contact with the fibrous preform.

9. (canceled)

10. The load according to claim 1, wherein the fibrous preforms are preforms of aircraft engine parts.

11. The load according to claim 1, wherein the gas inlet of each shaping housing is located between the first surface of said housing and the fibrous preform present in said housing and wherein the gas outlet of the housing is located between the second surface of said housing and the fibrous preform in the housing.

12. A method for manufacturing several parts of composite material comprising:
placing a plurality of fibrous preforms in a shaper in order to obtain the load according to claim 1,
consolidating the porous fibrous preforms by chemical vapor infiltration of a matrix, and
densifying the consolidated preforms.
